(19) United States
(12) Patent Application Publication
(10) Pub. No.: US 2008/0304054 A1
(43) Pub. Date: Dec. 11, 2008

(54) Method for Analyzing an Integrated Circuit, Apparatus and Integrated Circuit

(75) Inventors: Martijn Goosens, Veldhoven (NL); Frank Zachariasse, Wijchen (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/913,675

(22) PCT Filed: May 4, 2006
(86) PCT No.: PCT/IB2006/051402

§ 371 Date: Jun. 30, 2008

(30) Foreign Application Priority Data
May 5, 2005 (EP) 05103781.0

(51) Int. Cl. G01N 21/01; H01L 21/67; H01L 23/544

(52) U.S. Cl. 356/237.4; 29/25.01; 257/48; 257/E23.179

(57) ABSTRACT

A method for analyzing an integrated circuit (IC) comprising a plurality of semiconductor devices is disclosed. The method comprises the steps of forming a diffraction lens (100) comprising a plurality of concentric diffraction zones (110) in a first area of a further surface opposite to the first surface of the substrate (10), and a further step of optically accessing a subset (30) of the plurality of semiconductor devices (20) through the diffraction lens (100). Due to the fact that a diffraction lens (100) can be implemented at submicron sizes, the lens (100) can be formed more cheaply than a refraction lens, which usually is several microns deep. Moreover, the lens (100) can be easily polished off the substrate (10), which facilitates repeated relocation of the lens (100) on the substrate (10), thus improving the chance of optically detecting a fault inside the IC.

The present invention relates to a method for analyzing an integrated circuit comprising a plurality of semiconductor devices on a first surface of a substrate.

The present invention also relates to an apparatus for modifying the substrate of such an integrated circuit.

The present invention further relates to an integrated circuit comprising a plurality of semiconductor devices on a first surface of a substrate.

It is important for an integrated circuit (IC) manufacturer to optimize the manufacturing yield of the manufactured ICs, that is, to minimize the ratio between the number of good ICs and the number of faulty ICs manufactured. Firstly, due to the high cost involved with the production of integrated circuits (ICs), a high yield manufacturing process is essential to maintain competitiveness in a small-margin market. Moreover, the sale of a faulty IC can have a detrimental effect on the image of that product. For those reasons, an IC typically is tested rigorously before being sold to remove the faulty ICs from the manufactured batch.

In case of the detection of a faulty IC, it is important to determine the root cause of the fault, because this information can help to improve the yield of the IC manufacturing process. Unfortunately, IC tests are usually incapable of providing detailed enough information for the location of the fault on board the IC. Moreover, the IC test procedure often cannot identify every faulty IC in a batch, or an IC may break down during operation, which means that a faulty IC can be returned by a customer. In such cases, the fault on board the IC has to be located in a different way.

An example of a fault detection method using a focussed laser beam is given in U.S. Pat. No. 6,549,022, in which the IC under inspection is provided with a set of test vectors whilst a characteristic of the IC, e.g. the temperature of a preselected part of the IC, is altered to detect faulty behaviour of the IC. To this end, a focussed laser beam is used to increase the temperature of a subset of the semiconductor devices of the IC in an attempt to locate the fault within the subset. The power level of the laser beam can be varied to control the amount of temperature increase of the subset.

US patent application US 2004/0203257 discloses an alternative failure analysis method for a faulty IC. According to this method, a hemispherical cavity having a curved salient centre portion is etched in the backside of the substrate of the IC using a focussed ion beam etching technique. The cavity and its salient centre portion act as a solid immersion lens, which facilitates optical inspection of the internals of the IC. The lens has to be located at the backside of the IC substrate because the other side typically is covered by a number of metal layers that obscure the visibility of the internals of the IC. A disadvantage of this method is that a substantial part of the IC substrate has to be removed for the manufacturing of the solid immersion lens, which not only makes the method relatively costly but it usually also means that such a lens can only be formed once per substrate area. Consequently, if the solid immersion lens is formed in the wrong part of the substrate, and the fault is expected to be located in an area partially overlapping the area in which the solid immersion lens has been formed, the fault inside the IC cannot be detected, and the investment in the fault analysis has been wasted.

The present invention seeks to provide a cheaper and more flexible optical analysis method of ICs.

The present invention also seeks to provide an apparatus facilitating the implementation of such a method.

The present invention further seeks to provide an IC that is prepared for the execution of such a method.

According to an aspect of the present invention, there is provided a method for optically inspecting an integrated circuit comprising a plurality of semiconductor devices on a first surface of a substrate, the method comprising forming a diffraction lens comprising a plurality of concentric diffraction zones in a first area of a further surface of the substrate opposite the first surface of the substrate, and inspecting a subset of the plurality of semiconductor devices through the diffraction lens.

The invention is based on the realization that a diffraction lens, e.g. a Fresnel phase plate or zone plate can be efficiently implemented in the substrate of an IC, e.g. in a silicon substrate. In contrast to a solid immersion lens, a diffraction lens can be easily implemented at submicron scale, which reduces the time required for the formation of such a lens.

In a preferred embodiment of a phase plate, each diffraction zone is approximated by etching an n-th phase level structure into a part of the first area corresponding to the diffraction zone, with n being an integer of at least two. This facilitates an even more efficient implementation of such a diffraction lens at the cost of some optical efficiency compared to a diffraction lens having ideal diffraction zones. The n-th phase level structure can be formed by doping a first phase level of each diffraction zone with an etch resist prior to the etching step to create a difference in etching resistance between the various phase levels of a diffraction zone. Advantageously, a Gallium ion implant is used as an etch resist, because this can be achieved in a maskless step using a focussed ion beam, for instance.

Alternatively, the diffraction lens may be implemented as a zone plate by forming the plurality of diffraction zones as an alternating pattern of opaque zones and transparent zones. The opaque zones may be formed by depositing a layer of an opaque material on the first area, after which the alternating pattern is formed by selectively removing the opaque material to expose the transparent zones. Alternatively, the opaque zones may be formed by selectively depositing an opaque material on predefined parts of the first area. Both may be achieved in a maskless step by using a focussed ion beam.

Advantageously, the method further comprises the steps of removing the diffraction lens by polishing the further surface, etching a further diffraction lens having a further plurality of concentric diffraction zones in a further area of the further surface, and inspecting a further subset of the plurality of semiconductor devices through the further diffraction lens.

An important aspect of the invention is the realization that the small depth of the Fresnel lens facilitates the relocation of the lens on the substrate, which is not straightforward or even possible when using solid immersion lenses. Moreover, the diffraction lens of the present invention facilitates the use of a smaller optical path through the substrate compared to a carved-out solid immersion lens, which leads to less light absorption for wavelengths that the substrate weakly absorbs, e.g. the 1064 nm band of an IR laser in case of a silicon substrate. Consequently, the method of the present invention provides a dramatically improved chance of detecting the fault inside the IC. The present invention also provides an improved fault detection method compared to the fault detection method disclosed in aforementioned U.S. Pat. No. 6,549,022, since the laser beam can use the diffraction lens to focus on the subset, which improves the optical resolution of the fault detection method and consequently increases the chance that the fault on board the IC can be accurately detected.

It is pointed out that PCT patent application WO 91/02380 discloses an IC having an array of approximated refractive Fresnel lenses etched in the backside of its substrate, which carries an array of radiation detectors on the other side of the substrate. The lens array is arranged to focus the incident radiation on the radiation detectors. It will be appreciated that this is a substantially different use of a Fresnel lens. WO 91/02380 is silent about using a (Fresnel) diffraction lens per se, and does not teach that a Fresnel lens can be implemented more cheaply than a solid immersion lens or that a Fresnel lens can be relocated on the substrate. Consequently, neither the teachings of WO 91/02380 in isolation nor the combined teachings of WO 91/02380 and US 2004/0203257 would lead a skilled person to arrive at the present invention.

According to another aspect of the invention, there is provided an apparatus for modifying a substrate of an integrated circuit comprising a plurality of semiconductor devices on a first surface of a substrate, the apparatus comprising a preprogrammed function for generating a diffraction lens comprising a plurality of concentric diffraction zones in a first area of a further surface of the substrate opposite the first surface of the substrate for enabling optical access of a subset of the plurality of semiconductor devices through the diffraction lens. With such an apparatus, which may comprise a focussed ion beam generator, a diffraction lens can be routinely formed on a substrate of an IC selected for optical inspection.

For instance, the apparatus may be preprogrammed to form each diffraction zone by etching an n-th phase level structure into the first surface, n being an integer of at least two, the height of each level structure being smaller than a principal wavelength of the light used in the optical inspection to facilitate the implementation of a phase plate.

Alternatively, the apparatus may be preprogrammed to selectively pattern an opaque material deposited on the first area into the opaque zones in order to facilitate the formation of a zone plate. This can also be achieved by the apparatus being preprogrammed to implant or deposit an opaque material into predefined parts of the first area to form the opaque zones.

The invention is described in more detail and by way of non-limiting examples with reference to the accompanying drawings, wherein:

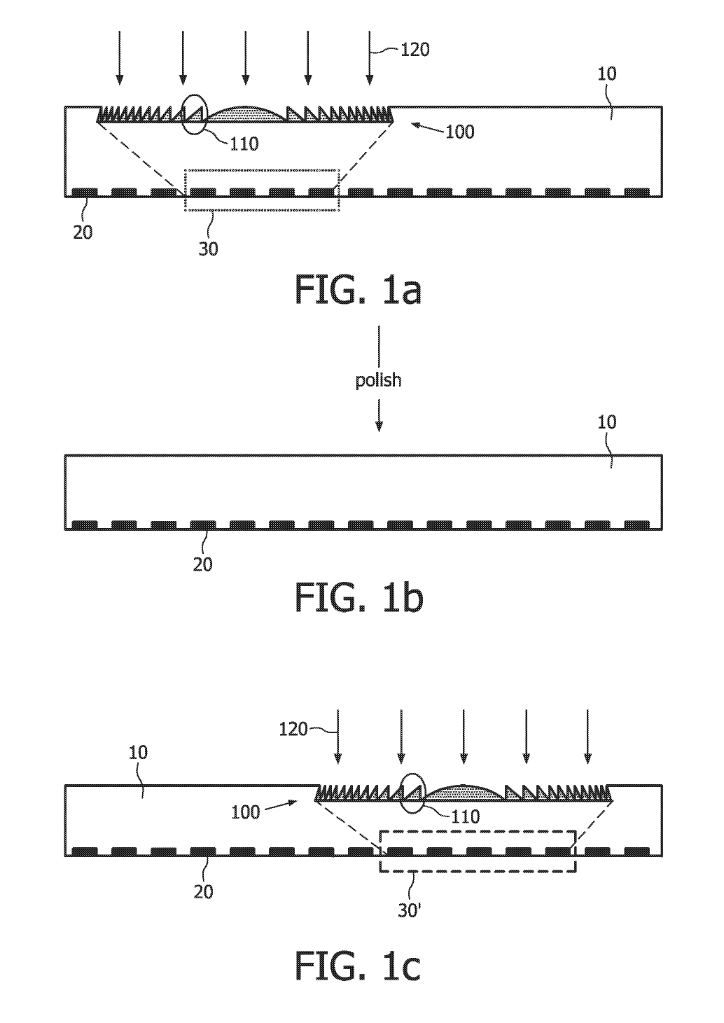

FIG. 1 schematically depicts an IC carrying a diffraction lens implemented as a phase plate;

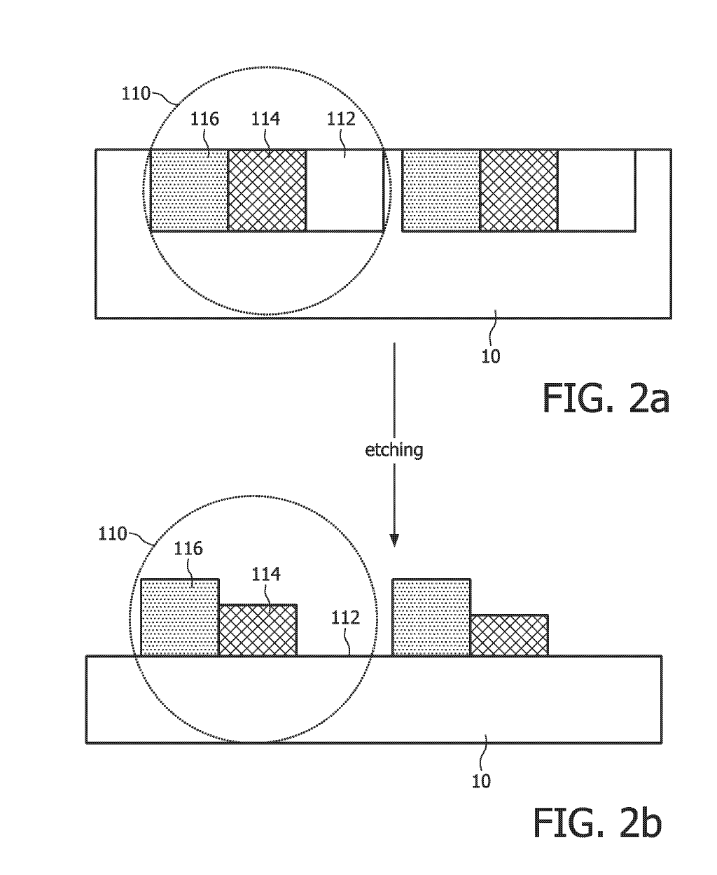

FIG. 2 depicts an embodiment of a method for producing a diffraction lens implemented as a 3-level phase approximated phase plate;

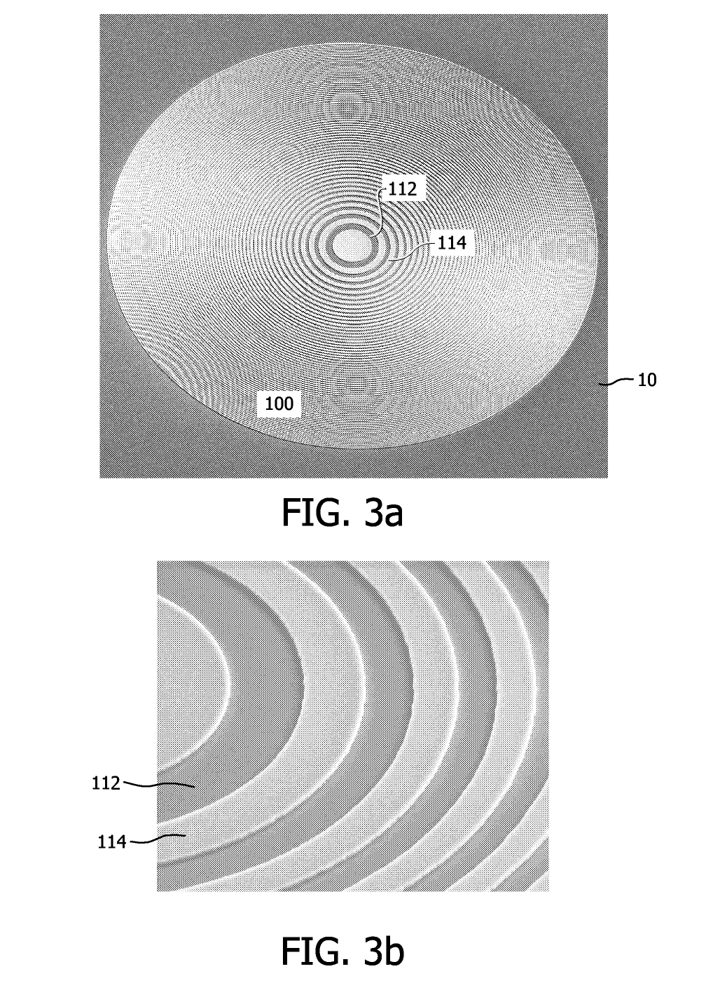

FIG. 3a shows an image of a diffraction lens implemented as a 2-level phase approximated phase plate in the substrate of an IC;

FIG. 3b shows a close-up image of the diffraction lens implemented as a 2-level phase approximated phase plate in the substrate of an IC;

FIG. 4 shows an image of a subset of a plurality of semiconductor devices on the substrate of an IC taken with a separate lens;

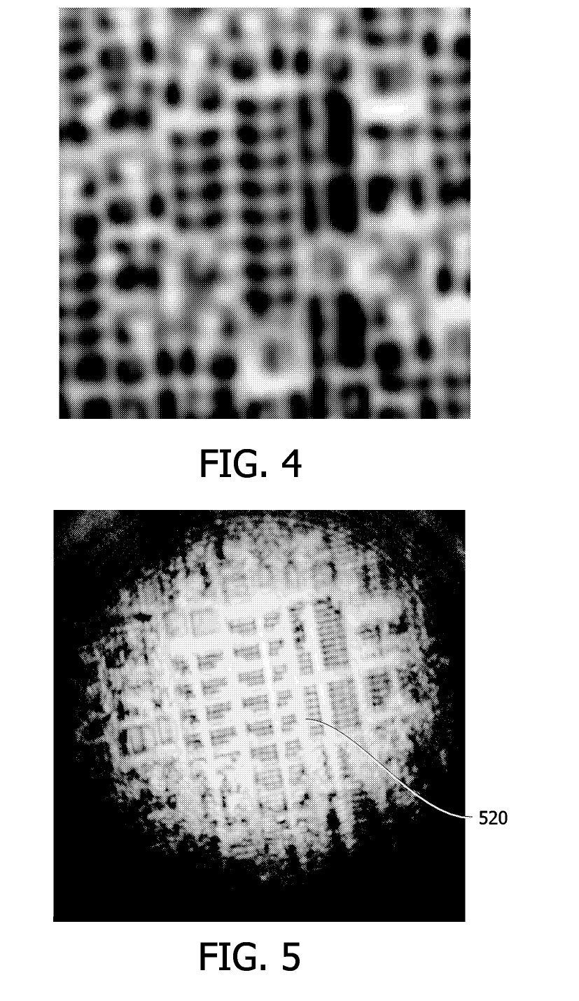

FIG. 5 shows an image of a smaller subset taken with a diffraction lens etched in the substrate of the IC;

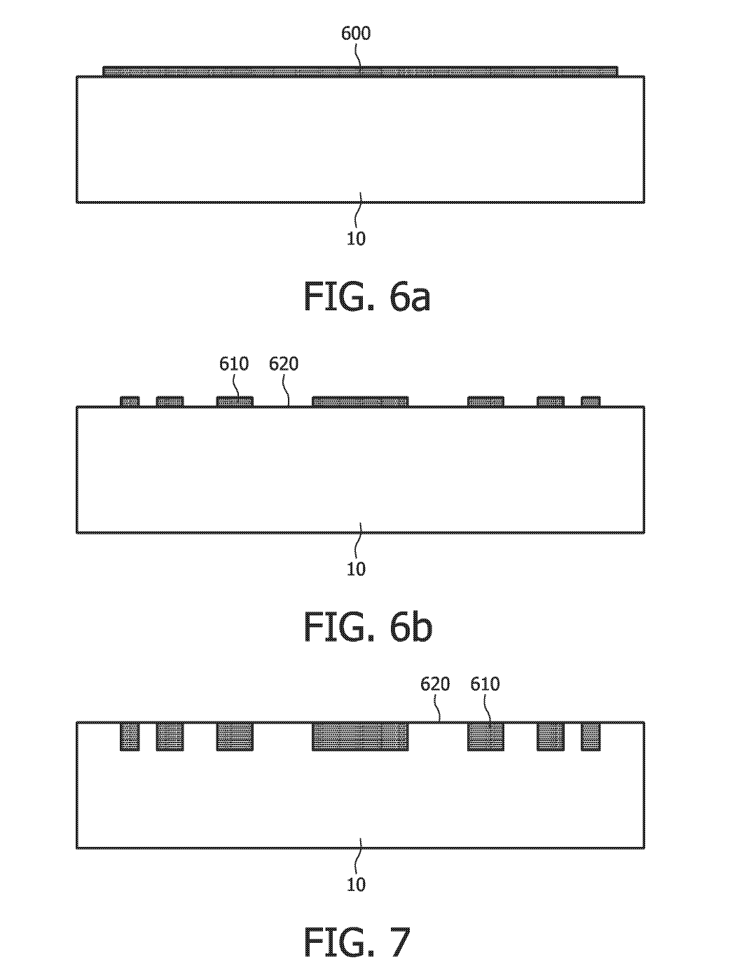

FIG. 6 shows an embodiment of a method for producing a zone plate on a substrate; and

FIG. 7 shows another embodiment of a method for producing a zone plate on a substrate;

It should be understood that the Figures are merely schematic and are not drawn to scale. It should also be understood that the same reference numerals are used throughout the Figures and their detailed description to indicate the same or similar parts.

FIG. 1 schematically depicts the inspection method of the present invention. The substrate 10 of an integrated circuit (IC) shown in (a) carries a plurality of semiconductor devices 20 on a first surface. The semiconductor devices 20 may be any known semiconductor device, e.g. transistors, diodes and so on, or aggregates thereof, e.g. logic cells or memory cells and so on. A diffraction lens 100 having a plurality of diffraction zones 110 is manufactured in a first area of the surface of the substrate 10 opposite the substrate surface carrying the semiconductor devices 20 to enable optical inspection of a subset 30 of the semiconductor devices 20 using electromagnetic radiation 120 of an appropriate wavelength, e.g. monochromatic infrared light generated by an infrared scanning laser based microscope (not shown) aligned with the diffraction lens 100. A separate lens (not shown), e.g. a solid immersion lens, may be used to further improve the optical resolution of the arrangement. It is emphasized that the main purpose of the IC inspection method of the present invention is IC fault detection, but that the inspection method of the present invention is not necessarily limited to this purpose.

The choice of the first area can be based on known inspection techniques, such as a preliminary optical inspection with a separate lens to approximate the location of the fault, e.g. a semiconductor device fault. Examples of such techniques can for instance be found in Soft Defect localization on ICs, Bruce et al. Proc. 28^{th} Intl. Symposium for Testing and Failure Analysis 2002, p. 21-27, or in the aforementioned U.S. Pat. No. 6,549,022. Such location methods are not always conclusive due to the limited optical resolution thereof. This lack of lateral resolution, which can lead to failure to accurately locate the fault, can be dramatically reduced by the use of a diffraction lens 100, as will be explained below.

An important characteristic of a diffraction lens 100, e.g. a Fresnel phase plate, is that the height of the diffraction zones 110 can be smaller than the wavelength of the light used in the optical inspection of the IC. This facilitates implementation of the diffraction lens 100 on submicron scales. For instance, when using infrared light having a wavelength in the 1000-1500 nm band, to which a silicon substrate 10 is transparent, the diffraction zones typically can have a submicron height, whereas the thickness of the substrate 10 usually is several tens to several hundreds of microns. This facilitates multiple relocations of the diffraction lens 100 on the substrate 10 because the removal of the diffraction lens 100 does not significantly reduce the thickness of the substrate 10. The diffraction lens 100 can be easily polished off the substrate 10 using common polishing techniques, rendering a plain substrate 10 as shown in (b), after which a new diffraction lens 100 can be formed on another area of the substrate 10 to inspect a further subset 30′ of semiconductor devices 20, as shown in (c). This relocation process can be repeated several times, thus greatly increasing the chance that the fault on board the IC can be located.

The diffraction lens 100 may be implemented as a Fresnel phase plate, which is sometimes also referred to as a phase-reversal zone plate, or as a Fresnel zone plate. The optical principles on which such devices are based are well known, and a detailed description thereof can be found in many optical text books, e.g. Optics, Fourth Edition (International Edition) by Eugene Hecht, Addison Wesley, San Francisco, 2002, pages 485-497, or in: Diffraction Based Solid Immersion Lens by Brunner et al., J. Opt. Soc. Am. A, 21, p. 1186-1191, 2004, which are hereby included by reference.

In short, a zone plate is based on the principle that successive Fresnel (or diffraction) zones can cancel each other out if their dimensions are appropriately chosen. This is caused by the fact that the parts of a wave front travelling through the successive zones experience a phase shift of π with respect to each other, which is caused by a difference in path length through the substrate 10 that the respective parts of the wave front travel through. This causes a destructive interference between the respective parts of the wave front in the focal point of the diffractive lens 100. To maximize the interference between the various parts of the wave front, the diffraction zones 110 should have substantially equal areas to ensure that the amplitudes of the diffracted light waves travelling through the various diffraction zones 110 are substantially equal. By blocking the even or the odd rank diffraction zones 110, i.e. by generating an alternating pattern of opaque and transparent zones 110, the wave fronts travelling through two neighbouring transparent zones 110 will experience a phase shift of 2π with respect to each other, thus leading to constructive interference at the expense of approximately 50% light intensity loss from the introduction of the opaque zones.

If such light intensity loss is unwanted, a phase plate can be constructed, in which the optical path length of a wave front through either the odd zones or through the even zones is ideally retarded by half a wavelength, i.e. by π. This phase shift turns the destructive interference between neighbouring zones of a zone plate into constructive interference between neighbouring zones of a phase plate. Because all diffraction zones 110 of a phase plate are in-phase with each other with respect to the wavelength λ of the light travelling through the diffraction zones 110, no zones need to be blocked and such a diffractive lens has a higher light efficiency than a zone plate. Obviously, the application of smaller retardations, e.g. by π/2 or π/4, also avoid the complete destructive interference of light travelling through neighbouring diffraction zones 110, albeit less effectively than a complete phase shift π.

The aforementioned retardation of the various parts of the wavefront is typically achieved by varying the height of neighbouring diffraction zones 110 to vary the thickness of the substrate 10 the respective parts of the wave front have to travel through. The retardation is based on the dependency of the propagation speed of light on the refractive index of the medium through which it travels. Hence, by having one part of the wave front travelling through a path length l of the substrate 10 and having a neighbouring part of the wave front travelling through a path length l formed by a first part l₁ through air and a second part l₂ through the substrate 10 (l₁+l₂=l), the propagation of the part of the wave front travelling through the substrate 10 over the full length of l can be delayed by the desired amount by the appropriate choice of l₁ and l₂.

Because the propagation delay over the full width of a diffraction zone 110 is also not constant, the diffraction zone 110 ideally has a very gradually varying thickness to compensate for the phase shift introduced by this variation in propagation delay. In practice, such ideal diffraction zones 110 are very difficult and costly to implement, and the diffraction zones 110 of a phase plate are usually approximated for that reason.

FIG. 2 shows an embodiment of a method for producing an approximated diffraction zone 110 of a diffraction lens 110 implemented as a phase plate. Each diffraction zone 110 is implemented as an N-level phase structure, that is, as a stepped structure having N steps. It will be appreciated that the larger N is chosen, the better the approximation of the ideal diffraction zone 110 is.

In FIG. 2, N=3 by way of example only. Although high N numbers have a better optical efficiency, low N numbers are preferred, e.g. N=2 or N=3, because low N numbers still yield a phase plate that has an acceptable optical efficiency and is straightforward to manufacture. It will be appreciated that the optical quality of the diffraction lens 100 can also be controlled in several other ways, e.g. by varying the number of diffraction zones 110 and/or by varying the diameter of the diffraction lens 100.

In a first step of the method, an etch resist is implemented in the steps 114 and 116 of the diffraction zone 110, as shown in (a). Such an etch resist may be an implant of Gallium ions implanted by a focussed ion beam. Step 116 has a higher concentration of etch resist than step 114 to ensure that step 114 more quickly etches away than step 116. Step 112 has an even lower etch resist concentration or no etch resist at all to ensure that step 112 etches away more quickly than step 114. In a next step, the surface of the substrate 110 is subjected to an etch step, e.g. a KOH etch or a plasma etch, which yields a diffraction zone 110 having a stepped structure as shown in (b). The height difference between each level structure 112, 114, 116 may be smaller than a principal wavelength of the light used in the optical inspection, although this is not strictly necessary.

Alternatively, the stepped structures 112, 114, 116 may be formed directly by milling the substrate 10 with a focussed ion beam for instance, in which case no etching step is required. This alternative method does lead to higher ion concentrations in the substrate than the etching method, which has the disadvantage that the optical quality of the diffraction lens 100 is reduced, due to the light absorbing nature of the implanted ions. Both methods have the advantage that no masks are required in the manufacturing steps of the diffraction lenses 100, which makes them cheap to implement. Moreover, the maskless nature of the manufacturing process of such diffraction lenses facilitates the addition of functionality directed to the manufacturing of such lenses on a substrate modifying apparatus such as a focussed ion beam generator. Such an apparatus can be extended with a preprogrammed function for generating a diffraction lens comprising a plurality of concentric diffraction zones, with the user of the apparatus only required to input certain key parameters, e.g. location of the first area on the substrate 10, focal distance to the semiconductor devices 20, required number of phase levels per diffraction zone 110 and so on, to enable the apparatus to routinely generate a diffraction lens 100 on the backside of the substrate 10.

At this point, it is emphasized that a diffraction lens 100 implemented as a phase plate can also be formed on the substrate 10 using conventional mask-based lithographic steps. It will, however, be evident that this is a more costly process than the proposed maskless manufacturing processes.

FIG. 3a shows a scanning electron micrographic image of the structure of a diffraction lens 100 implemented as a phase plate in a silicon substrate 10 of an IC using the method of FIG. 2. The diffraction zones of the diffraction lens 110 are implemented as a two-level phase structure, with N=2. The dark rings 112 correspond to the lower phase levels whereas the light rings 114 correspond to the raised phase levels. FIG. 3b is a close-up scanning electron micrographic image of the diffraction lens 100 of FIG. 3a, in which the height variations between the lower phase levels 112 and the raised phase levels 114 are even more clearly recognizable.

FIG. 4 shows a photographic image of the internals of an IC taken with an infrared scanning laser microscope through the backside of the substrate 10 of the IC, whereas FIG. 5 shows a photographic image taken with the same infrared scanning laser microscope of the same part of the IC through a diffraction lens 100 implemented as a phase plate in the substrate 10 of the IC. The image generated through the diffraction lens 100 shows a much higher degree of detail than the image generated by the separate refraction lens; for instance, individual transistor 520 is only visible in the image generated through the diffraction lens 100, which is a clear indication of the improved optical resolution and fault detection capability when using a diffraction lens 100 formed in the substrate 10 of the IC.

The main reasons for this difference in optical quality are that the diffraction lens 100 can be easily tailored to the specific optical requirements of the optical inspection, e.g. the lens can be defined corresponding to the thickness of the substrate 10, its required optical power and to the focal distance to the semiconductor devices 20, which in contrast is not possible with a fixed separate lens. Also, the diffraction lens 100 can be designed to be aspherical, which can be advantageous in situations where an aspherical lens is expected to generate a better quality image than a spherical lens. Furthermore, the image quality of the image generated by a separate lens can be hampered by quality of the contact surface between the lens and the substrate 10, whereas this problem does not occur with a diffraction lens 100 formed in the substrate 10.

FIG. 6 shows an embodiment of a method for producing a diffraction lens 110 implemented as a zone plate. In step (a), a film 400 of an opaque material, e.g. a metal film such as a titanium film is deposited over the selected area of the substrate 10. Next, the transparent diffraction zones 420 are formed by selectively removing the opaque material in a patterning step (b), which may be a maskless etching step involving a focussed ion beam. An example of such an etching process can for instance be found in: J. M. F. Zachariasse and J. F Walker, direct write patterning of titanium films using focused ion beam implantation and plasma etching, Microelectronic engineering 35 (1997), pages 63-66.

FIG. 7 shows an alternative embodiment of a method for producing a diffraction lens 110 implemented as a zone plate. An opaque material is implanted into, or deposited onto, selected regions of the substrate 10 to form the alternating pattern of opaque zones 410 and transparent diffraction zones 420. This can for instance be achieved by implanting Gallium ions in these regions with a focussed ion beam, or depositing a patterned metal layer on top of the substrate 10 by a focussed ion beam induced deposition.

The proposed manufacturing methods for a diffraction lens 100 implemented as a zone plate are also suitable for inclusion as a preprogrammed function on a substrate modifying device such as a focussed ion beam generator. Upon some user input, e.g. focal distance or number of required transparent zones 420, the apparatus can routinely calculate the size and location of the transparent zones 420 and opaque zones 410, and can modify the substrate 10 accordingly, i.e. by etching away the opaque material covering the transparent diffraction zones 420 or by directly implanting the opaque zones 420.

The various embodiments of the diffraction lens 100 can be advantageously used in various IC inspection methods, for instance to detect a fault in one or more of the semiconductor devices 20 inside an IC. For instance, a laser beam, e.g. an infrared laser beam, which may form a part of a microscope, can be focussed on the subset 30 of the semiconductor devices 20 with the aid of the diffraction lens 100 to gain optical access to the subset 30. This access may have various purposes, such as the purpose of generating an image of the subset 30 or the purpose of modifying a characteristic of the subset 30. The modification of a characteristic of the subset 30 may be an increase in temperature of the subset 30 by heating the subset 30, for instance. Typically, the modification will induce a change in the functional behaviour of the IC if the fault is located inside the subset 30.

This can be verified by providing the modified IC, that is, the IC including a subset 30 of semiconductor devices 20 with the modified characteristic, with a stimulus, e.g. a test pattern such as a test vector or a sine wave modulated analog test signal, and measuring the response of the modified IC to this stimulus. The response may be compared with a response of the IC to the same stimulus prior to the modification, i.e. to a response of the unmodified IC, to facilitate the evaluation of the effect of the modification on the behaviour of the IC. The main advantage of the method of the present invention is that if no measurable effect indicative of the presence of a fault within the subset 30 can be detected, the diffraction lens 100 can be easily relocated on the substrate 10, as previously explained, after which the inspection method can be repeated by inspecting the further subset 30′, e.g. by modifying a characteristic of the further subset 30′ and subsequently generating and evaluating a response of the IC to a stimulus as previously set out.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The invention can be implemented by means of hardware comprising several distinct elements. In the device claim enumerating several means, several of these means can be embodied by one and the same item of hardware. The mere fact that certain measures are recited in mutually different dependent claims does not indicate that a combination of these measures cannot be used to advantage.

1. A method for analyzing an integrated circuit comprising a plurality of semiconductor devices on a first surface of a substrate, the method comprising forming a diffraction lens comprising a plurality of concentric diffraction zones in a first area of a further surface of the substrate opposite the first surface of the substrate; and optically accessing a subset of the plurality of semiconductor devices through the diffraction lens.

2. A method as claimed in claim 1, further comprising forming each diffraction zone by etching an n-th phase level structure into a part of the first area corresponding to the diffraction zone, n being an integer of at least two.

3. A method as claimed in claim 2, wherein the etching step is preceded by doping a first phase level of each diffraction zone.

4. A method as claimed in claim 3, wherein the step of doping the first phase level of each diffraction zone comprises implanting a Gallium ion doping profile in the first phase level.

5. A method as claimed in claim 1, further comprising forming the plurality of diffraction zones as an alternating pattern of opaque zones and transparent zones.

6. A method as claimed in claim 5, wherein the step of forming the plurality of diffraction zones as an alternating pattern of opaque zones and transparent zones comprises depositing a layer of an opaque material on the first area, and wherein the alternating pattern is formed by selectively removing the opaque material.

7. A method as claimed in claim 5, further comprising forming the opaque zones by selectively depositing an opaque material on predefined parts of the first area.

8. A method as claimed in claim 1, wherein the optically accessing step comprises optically accessing the subset of the plurality of semiconductor devices with a laser beam using the diffraction lens to focus the laser beam on the subset.

9. A method as claimed in claim 8, the optically accessing step further comprising modifying the integrated circuit by modifying a characteristic of the subset of the plurality of semiconductor devices with the laser beam.

10. A method as claimed in claim 9, further comprising providing the modified integrated circuit with a stimulus and measuring a response of the modified integrated circuit to the stimulus.

11. A method as claimed in claim 10, further comprising comparing the response with a response of the unmodified integrated circuit.

12. A method as claimed in claim 1 further comprising the steps of removing the diffraction lens by polishing the further surface, forming a further diffraction lens having a further plurality of concentric diffraction zones in a further area of the further surface, and inspecting a further subset of the plurality of semiconductor devices through the further diffraction lens.

13. An apparatus for modifying a substrate of an integrated circuit comprising a plurality of semiconductor devices on a first surface of a substrate, the apparatus comprising a preprogrammed function for generating a diffraction lens comprising a plurality of concentric diffraction zones in a first area of a further surface of the substrate opposite the first surface of the substrate for enabling optical access of a subset of the plurality of semiconductor devices through the diffraction lens.

14. An apparatus as claimed in claim 13, wherein the apparatus is preprogrammed to form each diffraction zone by etching an n-th phase level structure into the first surface, n being an integer of at least two, the height of each level structure being smaller than a principal wavelength of the light used in the optical inspection.

15. An apparatus as claimed in claim 13, wherein the plurality of diffraction zones comprises an alternating pattern of opaque zones and transparent zones, the apparatus being preprogrammed to selectively pattern an opaque material deposited on the first area into the opaque zones.

16. An apparatus as claimed in claim 13, wherein the plurality of diffraction zones comprises an alternating pattern of opaque zones and transparent zones, the apparatus being preprogrammed to implant an opaque material into predefined parts of the first area to form the opaque zones.

17. An integrated circuit comprising a substrate and a plurality of semiconductor devices on a first surface of the substrate, the integrated circuit further comprising a diffraction lens comprising a plurality of concentric diffraction zones in a first area of a further surface of the substrate opposite the first surface of the substrate for inspecting a subset of the plurality of semiconductor devices.
